(19) United States
(12) Patent Application Publication
(10) Pub. No.: US 2004/0007742 A1
(43) Pub. Date: Jan. 15, 2004

(54) Pure silcide ESD protection device

(76) Inventors: Tao Cheng, Kaoshiung (TW); Jian-Hsing Lee, Hsin-Chu (TW)

Correspondence Address: GEORGE O. SAILE & ASSOCIATES, 28 DAVIS AVENUE, POUGHKEEPSIE, NY, 12603, US

(21) Appl. No.: 10/193,445

(22) Filed: Jul. 11, 2002

(51) Int. Cl. H01L 23/62

(52) U.S. Cl. 257/355

(57) ABSTRACT

A new device for shunting electrostatic discharge (ESD) energy from a pad of an integrated circuit device has been achieved. The device comprises, first, a substrate of a first dopant type. A plurality of source junctions of a second dopant type are in the substrate. A silicide layer overlies all of each of the source junctions and this silicide layer is in contact with a first conductive layer that is a ground reference. A plurality of drain junctions of the second dopant type are in the substrate. The silicide layer overlies all of each of the drain junction and this part of the silicide layer is in contact with a second conductive layer that is connected to the pad. Finally, a gate comprising a third conductive layer overlies the substrate between each of the source junctions and the drain junctions with an insulating layer therebetween. The gate is connected to the ground reference.

### BACKGROUND OF THE INVENTION

(1) Field of the Invention

The invention relates to a device for electrostatic discharge (ESD) protection, and more particularly, to a novel, pure silicide device for use in a CMOS integrated circuit device.

(2) Description of the Prior Art

As device dimensions continue to be reduced, susceptibility to electrostatic discharge (ESD) damage is a growing concern. ESD events occur when charge is transferred between one or more pins of an integrated circuit and another conducting object in a short period of time, typically less than one microsecond. The rapid charge transfer generates voltages large enough to breakdown insulating films, such as silicon dioxide, and to cause permanent damage to the device. To deal with the problem of ESD events, integrated circuit manufactures have designed various structures on the input and output pins to shunt ESD currents away from sensitive internal structures.

Referring now to FIG. 1, a prior art CMOS input circuit is illustrated. In this circuit, an input pad, PAD 10, is connected to the internal circuit, represented by the inverter 22. An input protection stage is used to protect the internal circuit 22 from any ESD events, such as V_{ESD}, occurring on PAD 10. The input protection stage comprises a protection resistor, R_{RPO} 14, and an active protection device 18. The input protection stage functions as a shunting path to shunt excessive voltages through the protection device 18 to ground 26 during an ESD event.

The protection device 18 can be any active device that meets the requirements of, first, being open circuited during all normal operating conditions, and, second, being short circuited during an ESD event. The purpose of the protection resistor, R_{RPO} 14, is to limit the current flow through the protection device 18 during the ESD event. The protection resistor 14 is typically called a resistor to protect oxide, or simply, RPO.

Referring now to FIG. 2, a simplified example of a device that combines the RPO and a shunting transistor is illustrated. An input pad, PAD 54, is connected to at least one drain junction 62. The drain junction 62 comprises an n+ region that is formed in the p-type substrate 50. The drain junction 62 is located near at least one source junction 58 that is also doped n+. An MOS gate 84 and 80 is formed overlying the substrate 50 in the area between the drain junction 62 and the source junction 58. Here, the MOS gate is shown as, for example, a polysilicon layer 80 with a silicide layer 84 overlying. The gate insulator is not shown. Note that an NMOS transistor is formed wherein the gate 84 and 80 and the source 58 are tied to ground. This configuration is commonly called a grounded-gate NMOS configuration. The substrate 50 is also tied to ground through the substrate tie junctions 66 that are doped p-type (p+)

An important feature of this device is the selective use of a silicide layer 72 in the drain junctions 62. The silicide layer 72 is formed overlying all of the source junctions 58 and substrate tie junctions 66. However, the silicide layer 72 is formed only on the part of the drain junctions 62 where contact is made. The purpose of the silicide layer 72 is to reduce the resistivity of the junction and to reduce the contact resistance. The part of the drain junctions 62 where the silicide layer 72 is not formed is of higher resistivity. Since this non-silicide area is in series with the drain current, an R_{RPO} resistor is formed. This R_{RPO} again acts as a current limiting resistor during an ESD event.

During an ESD event, the parasitic n-p-n devices 88 are turned on due to substrate current and the voltage drop that is induced by the relatively large resistance of the substrate (R_{SUB}). The turn-on of these parasitic bipolar devices causes a phenomenon known as snapback to occur. During snapback, the protection device clamps the pad voltage to a small value relative to the magnitude of the ESD spike. The energy of the spike is then shunted into the ground reference through the parasitic bipolar devices of the grounded-gate NMOS transistor.

The example device exhibits several problems, however. First, the drain junctions 62 with R_{RPO} require that an RPO mask be used to shield these areas from silicide formation. Second, an extra ion implantation must be performed to improve the performance of the device. In addition, the snapback voltage can be too large to adequately protect the internal circuits.

Referring now to FIG. 7, another problem with the prior art device is shown. When the RPO type of device is used for a deep sub-micron process, the device exhibits a problem called current crowding 96. The cross sectional view shows the current flow distribution 94 for the device during a simulated ESD event. For a large geometry device having, for example, a gate length of greater than 1 micron, it is found that current flow is crowded, or localized, at the drain silicide region 97 during an ESD event. However, in a deep sub-micron device, having a gate length of less than about 0.2 microns, the current crowding effect is located at the edge 96 of the lightly doped drain 93 on the drain side. Because of this effect, the RPO ESD device exhibits poor current uniformity. Since the current flow during an ESD event is localized in a single section 96 of an otherwise large protection structure, it fails at a prematurely low voltage. Many prior art approaches that teach the use of an RPO process are no longer useful in the deep sub-micron range.

Several prior art inventions describe ESD devices and circuits. U.S. Pat. No. 5,985,722 to Kishi teaches NMOS and PMOS ESD protection and output devices. Silicide in the drain areas is offset from the gate by using a patterned insulator layer. U.S. Pat. No. 6,046,480 to Matsumoto et al discloses an ESD protection circuit where the drain of the output device contains silicide under the contact only. U.S. Pat. No. 6,121,092 to Liu et al discloses a method to form MOS ESD protection devices. The silicide is blocked from forming in a portion of the output drains by using a blocking layer. U.S. Pat. No. 5,982,600 to Cheng teaches an ESD protection device comprising an NMOS device and a p-type junction with an isolation region therebetween. Silicide may be used with this device to improve the contact resistance. U.S. Pat. No. 4,855,620 to Duvvury et al discloses an output buffer with improved ESD performance. A low threshold voltage transistor and a high threshold voltage transistor are used in the output buffer.

C. H. Dias et al, in the article, “Building-In ESD/EOS Reliability for Sub-Halfmicron CMOS Processes,” IEEE Transactions on Electron Devices, Vol. 43, No. 6, June 1996, pp. 991-999, discloses an ESD/EOS device comprising a grounded-gate NMOS transistor. A double-diffused drain (DDD) is used to improve ESD performance. J. Z. Chen et al, in the article, “Design Methodology and Optimization of Gate-Driven NMOS ESD Protection Circuits in Submicron CMOS Processes,” IEEE Transactions on Electron Devices, Vol. 45, No. 12, December 1998, pp. 2448-2456, discloses an NMOS ESD protection device driven by a p-n-p transistor, a capacitor, and a resistor. The p-n-p device increases the NMOS gate voltage during an ESD event to thereby increase the secondary breakdown voltage. T. L. Polgreen et al, in the article, “Improving the ESD Failure Threshold of Silicided NMOS Output Transistors by Ensuring Uniform Current Flow,” IEEE Transactions on Electron Devices, Vol. 39, No. 2, February 1992, pp. 379-388, discloses an improved ESD failure threshold for an NMOS device. A technique of floating the substrate by using split buses yields the best results. G. Notermans et al, in the article, “The Effects of Silicide on ESD Performance,” IEEE 37^{th} Annual International Reliability Physics Symposium, 1999, pp. 154-158, shows the effects of the presence of silicide layers on the performance of NMOS devices during ESD events.

### SUMMARY OF THE INVENTION

A principal object of the present invention is to provide an effective and very manufacturable device for shunting electrostatic discharge (ESD) energy from a pad of an integrated circuit device.

A further object of the present invention is to provide an ESD protection device using pure silicide, without an RPO resistor.

A still further object of the present invention is to eliminate the need for the RPO mask.

Another still further object of the present invention is to achieve better current uniformity in a ground-gate NMOS ESD protection device in a deep sub-micron process.

Another still further object of the present invention is to implement the device using minimum design rules for polysilicon spacing and contact-to-polysilicon spacing.

In accordance with the objects of this invention, a new device for shunting electrostatic discharge (ESD) energy from a pad of an integrated circuit device has been achieved. The device comprises, first, a substrate of a first dopant type. A plurality of source junctions of a second dopant type are in the substrate. A silicide layer overlies all of each of the source junctions and this silicide layer is in contact with a first conductive layer that is a ground reference. A plurality of drain junctions of the second dopant type are in the substrate. The silicide layer overlies all of each of the drain junctions and the silicide layer is in contact with a second conductive layer that is connected to the pad. Finally, a gate comprising a third conductive layer overlies the substrate between the source junctions and the drain junctions with an insulating layer therebetween. The gate is connected to the ground reference.

### BRIEF DESCRIPTION OF THE DRAWINGS

In the accompanying drawings forming a material part of this description, there is shown:

FIG. 1 illustrates a prior art input circuit with ESD protection devices, including a resistor for protecting oxide (RPO).

FIG. 2 illustrates in cross section a prior art ESD protection device using RPO and grounded-gate NMOS devices.

FIG. 3 illustrates a top, layout view of the preferred embodiment, pure silicide ESD protection device of the present invention.

FIG. 4 illustrates a cross section of the preferred embodiment, pure silicide ESD protection device of the present invention.

FIG. 5 illustrates the device model of the preferred embodiment, pure silicide ESD protection device of the present invention.

FIG. 6 shows the performance of the preferred embodiment device of the present invention compared to the prior art device.

FIG. 7 illustrates the prior art problem of current crowding at the LDD edge for a deep sub-micron, RPO process.

### DESCRIPTION OF THE PREFERRED EMBODIMENTS

The preferred embodiment discloses a device of the present invention for ESD protection of an integrated circuit device. It should be clear to those experienced in the art that the present invention can be applied and extended without deviating from the scope of the present invention.

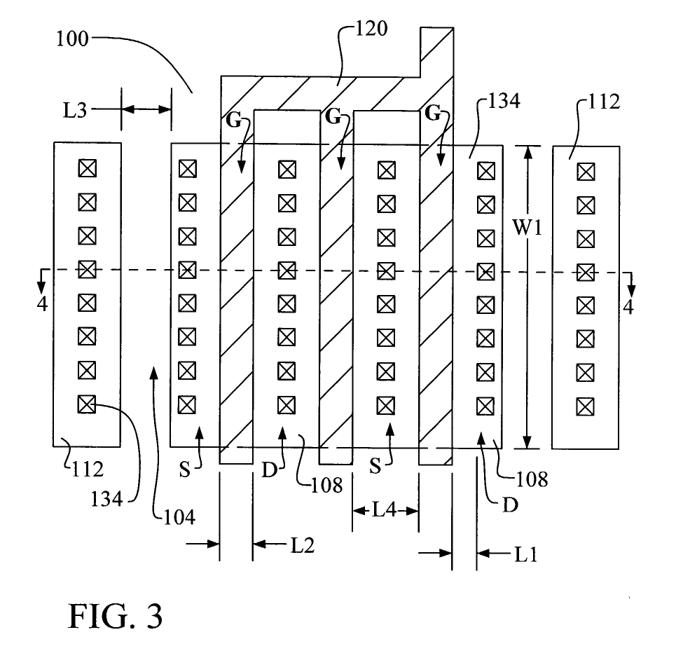

Referring now particularly to FIG. 3, there is shown the preferred embodiment of the pure silicide ESD protection device of the present invention. Several important features of the present invention are shown in this illustration. The device of the present invention is shown in a top view layout. A relatively small section of the device of the present invention is shown.

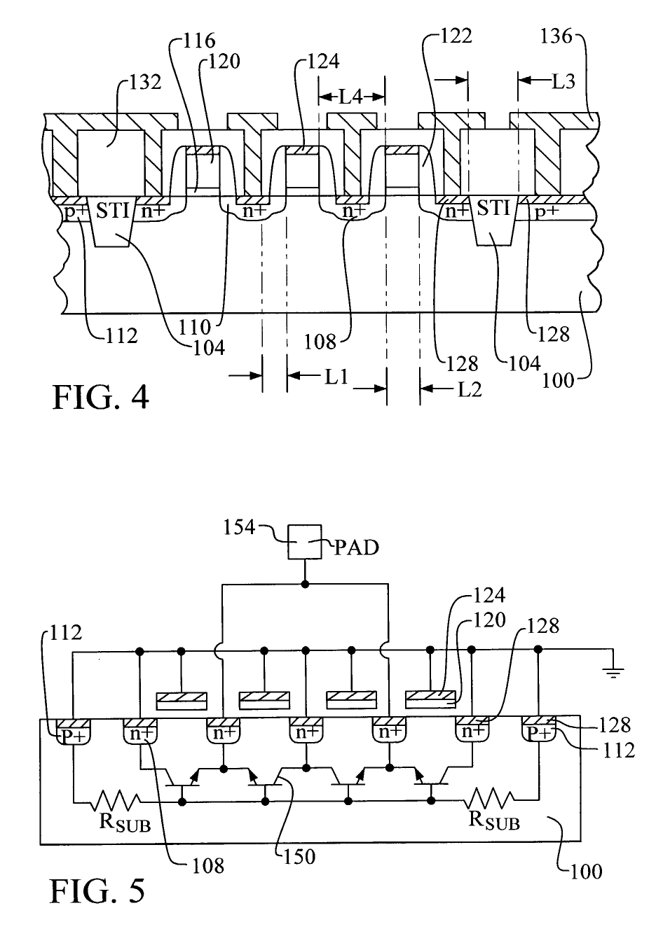

A conductive layer 120 is patterned to form the gate for the device. The conductive layer 120 preferably comprises polysilicon that is deposited and patterned by conventional means. The conductive layer 120 overlies a substrate 100 as will be more clearly seen in the cross section of FIG. 4. An insulating layer, not shown, is between the conductive layer 120 and the substrate 100. The substrate 100 comprises a first type of doping, and preferably is lightly doped p-type. A plurality of source (S) junctions and drain (D) junctions 108 are in the substrate 100. The source and drain junctions 108 are of a second doping type, and preferably comprise heavily doped n-type (n+). Substrate tie junctions 112 are in the substrate 100. The substrate tie junctions 112 comprise the same doping type as the substrate 100, and more preferably, comprise heavily doped p-type (p+).

Several important features are shown in the layout diagram. First, the conductive layer 120 forms a single gate comprising several “fingers.” In the diagram, three gate “fingers” are shown. In practice, many more gate “fingers” would be formed in a very large device. Each gate line of the conductive layer 120 is preferably formed using the minimum line width L2 for this layer in the manufacturing process. For example, in a submicron CMOS process, the conductive layer line width L2 is between about 0.3 microns and 0.4 microns. This feature is important because it allows the protection device to be formed as small as possible. This line width L2 of the conductive layer 120 creates the transistor length of the protection device.

A second key feature of the layout of the preferred embodiment is the width W1 of the overlap of the gate fingers 120 and the plurality of the source and drain junctions 108. This width W1 may be multiplied by the number of gate fingers to obtain the total width of the MOS device, in this case, 3×W1. In the preferred embodiment, the total width of the protection device is between about 200 microns and 1200 microns. By constructing the device of the preferred embodiment sufficiently large, a very large interlaced parasitic n-p-n structure can be created.

A third key feature of the layout is the distance L1 between the edges of the conductive layer 120 and the contact openings 134 in the source and drain junctions 108. The contact openings 134 are formed through a dielectric layer, not shown, for contact between the source and drain junctions 108 and a connective layer, not shown, that overlies the dielectric layer. Most importantly, the edges of the contact openings 134 are preferably spaced the minimum distance L1 from the edges of the gate fingers 120 allowed by the process. For example, the gate to contact spacing L1 is preferably between about 0.1 microns and 0.15 microns.

A fourth important feature is the spacing L4 between adjacent gate fingers 120. This spacing L4 may be made at the minimum spacing for the conductive layer 120 in the process. For example, the gate spacing L4 is preferably between about 0.4 microns and 0.5 microns.

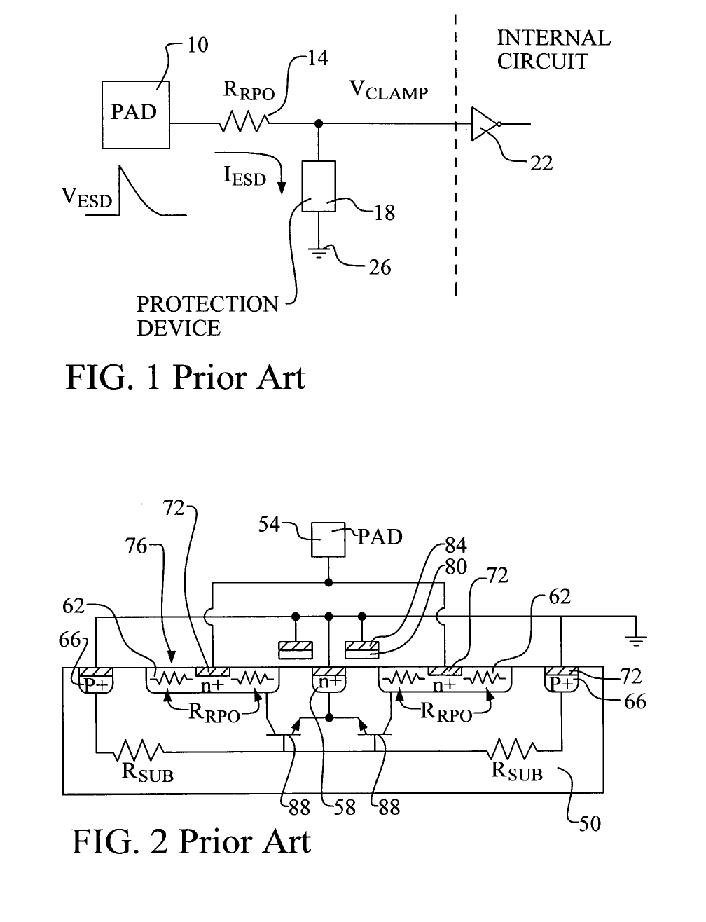

As will be seen more clearly in the cross section of FIG. 4, the entire drain and source junction 108 area may have a silicide layer, not shown, formed thereon. This is especially significant in light of the example device of FIG. 1 where a non-silicide area must be formed between the contact opening and the gate edge. The device of the present invention uses a silicide layer overlying the entirety of the drain and source junctions 108 and thereby eliminates the need for a silicide blocking mask or an RPO mask. Further, the performance of the device is improved as will be seen in the data presented in the sections following. Finally, the elimination of the large RPO areas greatly increases the layout efficiency for the ESD protection device of the present invention.

A fifth important feature of the layout is the spacing L3 between the substrate tie junctions 112 and the periphery source and drain junctions 108. The spacing comprises a non-active area 104 of the substrate 100 that preferably comprises an isolation layer such as shallow trench isolation. The preferred spacing L3 is between about 0.2 microns and 0.3 microns and plays a key role in achieving an optimal substrate resistance for the device during snapback operation.

Referring now to FIG. 4, a cross section of the preferred embodiment of the device of the present invention is illustrated. In this view, several important features are more clearly shown. First, the gates for each finger comprise a stack preferably comprising the insulating layer 116, the conductive layer 120, and a silicide layer 124. The silicide layer may comprise, for example, one of the group consisting of cobalt silicide, titanium silicide, and nickel silicide. In addition, sidewall spacers 122 may be formed on the gate stack to create an offset for lightly doped drains 110 to provide consistency with the CMOS process.

A particularly key feature is the presence of the silicide layer 128 overlying the drain and source junctions 108. Once again, this silicide layer may comprise, for example, one of the group of consisting of cobalt silicide, titanium silicide, and nickel silicide. Contrary to the example case of FIG. 2, the silicide layer 128 overlaps the entire heavily doped drain and source junctions 108 between the sidewall spacers 122. In this way, the RPO are eliminated along with the additional processing steps necessary to produce the RPO. A conformal metal layer may be deposited. The silicide layers 124 and 128 are then formed over the exposed polysilicon and silicon. Finally, the dielectric layer 132, shallow trench isolations 104, and connective layer 136 are clearly shown.

Referring now to FIG. 5, a model of the device is illustrated. In this model, the preferred connectivity is also illustrated. The input PAD 154 is connected to the drains 108 of the ESD device. The sources and gates 124 and 120 are connected to the ground reference. The substrate ties 112 are also tied to the ground reference. Parasitic n-p-n transistors 150 are created in the substrate 100. These transistors 150 turn ON during an ESD event.

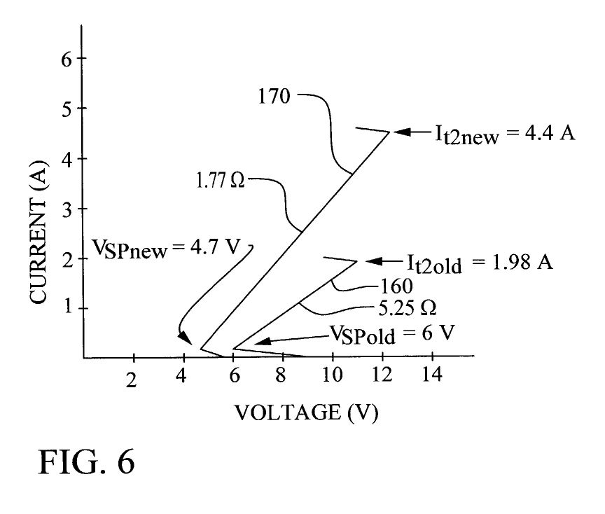

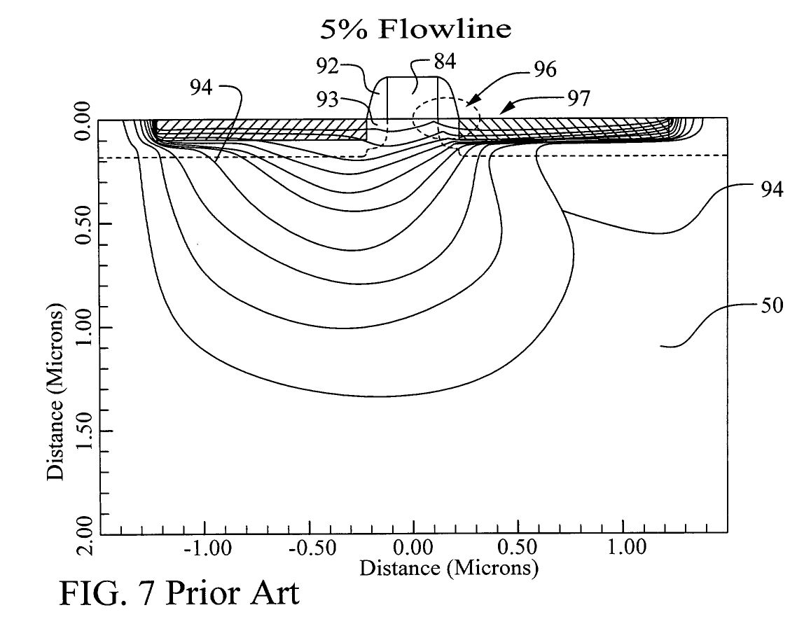

Referring now to FIG. 6, the performance of the preferred embodiment of the device of the present invention is compared to the RPO style device of FIG. 2. The ESD performance of the RPO device is shown as the snapback curve 60. The RPO snapback voltage, V_{SPOld}, is about 6 Volts. By comparison, the pure silicide device advantageously reduces the snapback voltage, V_{SPNew}, to about 4.7 Volts as shown by data line 170. This reduced snapback voltage provides improved protection for internal devices by shunting the ESD current at a lower voltage.

The thermal run-away current, I_{t2Old}, is about 2 Amps in the RPO version. By comparison, I_{t2New} is about 4.4 Amps for a same size device of the preferred embodiment. The increased thermal run-away limit means that the device is capable of shunting a greater amount of current before failure. The new device presents a lower ON resistance of about 1.77 Ohms compared to the prior art device value of about 5.25 Ohms.

Most importantly, the novel device of the present invention exhibits superior ESD performance of greater than about 8 kilovolts compared to about 3 kilovolts for the RPO device in a human body model (HBM) test. The present invention achieves an ESD performance of about 400 Volts for the machine model (MM). The RPO device exhibits a MM ESD performance of about 250 Volts. The advantages of the present invention over the prior art are achieved through the combination of a pure silicide, or non-RPO, device with the small layout guidelines described above. While the prior art teaches combining large layout guidelines, particularly with regards to polysilicon gate size and contact to gate spacing, the present invention uses minimum feature sizes available in the deep sub-micron process. It is found that combining minimum features and pure silicide and, more preferably, the multiple finger layout, provides a device with a significantly higher ESD performance than available in the prior art.

The advantages of the present invention may now be summarized. First, an improved ESD performance is achieved. Second, the present invention eliminates the need for the RPO mask. Finally, the device of the present invention may be easily incorporated into a typical CMOS process.

As shown in the preferred embodiments, the novel protection circuit device and method of the present invention provide an effective and manufacturable alternative to the prior art.

While the invention has been particularly shown and described with reference to the preferred embodiments thereof, it will be understood by those skilled in the art that various changes in form and details may be made without departing from the spirit and scope of the invention.

What is claimed is:

1. A device for shunting electrostatic discharge (ESD) energy from a pad of an integrated circuit device comprising:
a substrate of a first dopant type;
a plurality of source junctions of a second dopant type in said substrate wherein a silicide layer overlies all of each of said source junctions and wherein said silicide layer of each of said source junctions is in contact with a first conductive layer that is a ground reference;
a plurality of drain junctions of said second dopant type in said substrate wherein said silicide layer overlies all of each of said drain junctions and wherein said silicide layer of each of said drain junctions is in contact with a second conductive layer that is connected to said pad; and
a gate comprising a third conductive layer overlying said substrate between said source junctions and said drain junctions with an insulating layer therebetween wherein said gate is connected to said ground reference.

2. The device according to claim 1 wherein said first dopant type comprises p-type and said second dopant type comprises n-type.

3. The device according to claim 1 wherein said gate has a length of between about 0.3 microns and 0.4 microns.

4. The device according to claim 1 wherein said gate has a width of between about 200 microns and 1200 microns.

5. The device according to claim 1 wherein adjacent segments of said gate are spaced between about 0.4 microns and 0.5 microns.

6. The device according to claim 1 further comprising a dielectric layer overlying said substrate, said plurality of source junctions, said plurality of drain junctions, and said gate wherein said contacts between said silicide layer of each of said source junctions and said first conductive layer and said contacts between said silicide layer of each of said drain junctions and said second conductive layer are through openings in said dielectric layer and wherein said openings are spaced from said gate between about 0.1 microns and 0.15 microns.

7. The device according to claim 1 further comprising sidewall spacers on said gate wherein said source junctions and said drain junctions are spaced from said gate by said sidewall spacers and wherein lightly doped drain junctions underlie said sidewall spacers.

8. The device according to claim 1 further comprising a substrate tie junction of said first dopant type in said substrate wherein said substrate tie junction is connected to said ground reference and wherein said substrate tie junction is spaced from the nearest said source junction and said drain junction between about 0.2 microns and 0.3 microns.

9. A device for shunting electrostatic discharge (ESD) energy from a pad of an integrated circuit device comprising:
a substrate of p-type;
a plurality of source junctions of n-type in said substrate wherein a silicide layer overlies all of each of said source junctions and wherein said silicide layer of each of said source junctions is in contact with a first conductive layer that is a ground reference;
a plurality of drain junctions of n-type in said substrate wherein said silicide layer overlies all of each of said drain junctions and wherein said silicide layer of each of said drain junctions is in contact with a second conductive layer that is connected to said pad; and
a gate comprising polysilicon overlying said substrate between said source junctions and said drain junctions with an insulating layer therebetween wherein said gate is connected to said ground reference wherein adjacent segments of said gate are spaced not more than 0.5 microns;

10. The device according to claim 9 wherein said gate has a length of between about 0.3 microns and 0.4 microns.

11. The device according to claim 9 wherein said gate has a width of between about 200 microns and 1200 microns.

12. The device according to claim 9 further comprising a dielectric layer overlying said substrate, said plurality of source junctions, said plurality of drain junctions, and said gate wherein said contacts between said silicide layer of each of said source junctions and said first conductive layer and said contacts between said silicide layer of each of said drain junctions and said second conductive layer are through openings in said dielectric layer and wherein said openings are spaced from said gate between about 0.1 microns and 0.15 microns.

13. The device according to claim 9 further comprising sidewall spacers on said gate wherein said source junctions and said drain junctions are spaced from said gate by said sidewall spacers and wherein lightly doped drain junctions underlie said sidewall spacers.

14. The device according to claim 9 further comprising a substrate tie junction of p-type in said substrate wherein said substrate tie junction is connected to said ground reference and wherein said substrate tie junction is spaced from the nearest said source junction and said drain junction between about 0.2 microns and 0.3 microns.

15. The device according to claim 9 wherein said silicide layer comprises one of the group consisting of cobalt silicide, titanium silicide, and nickel silicide.

16. A device for shunting electrostatic discharge (ESD) energy from a pad of an integrated circuit device comprising:
a substrate of p-type;
a plurality of source junctions of n-type in said substrate wherein a silicide layer overlies all of each of said source junctions and wherein said silicide layer of each of said source junction is in contact with a first conductive layer that is a ground reference;
a plurality of drain junctions of n-type in said substrate wherein said silicide layer overlies all of each of said drain junctions and wherein said silicide layer of each of said drain junctions is in contact with a second conductive layer that is connected to said pad;
a gate comprising polysilicon overlying said substrate between said source junctions and said drain junctions with an insulating layer therebetween wherein said gate is connected to said ground reference, wherein adjacent segments of said gate are spaced not more than 0.5 microns;
a substrate tie junction of p-type in said substrate wherein said substrate tie junction is connected to said ground reference; and
a dielectric layer overlying said substrate, said plurality of source junctions, said plurality of drain junctions, and said gate wherein said contacts between said silicide layer of each of said source junctions and said first conductive layer and said contacts between said silicide layer of each of said drain junctions and said second conductive layer are through openings in said dielectric layer and wherein said openings are spaced from said gate not more than 0.15 microns.

17. The device according to claim 16 wherein said gate has a length of between about 0.3 microns and 0.4 microns.

18. The device according to claim 16 wherein said gate has a width of between about 200 microns and 1200 microns.

19. The device according to claim 16 further comprising sidewall spacers on said gate wherein said source junctions and said drain junctions are spaced from said gate by said sidewall spacers and wherein lightly doped drain junctions underlie said sidewall spacers.

20. The device according to claim 16 wherein said silicide layer comprises one of the group consisting of cobalt silicide, titanium silicide, and nickel silicide.
